(19) United States
(12) Patent Application Publication
(10) Pub. No.: US 2026/0040720 A1
(43) Pub. Date: Feb. 5, 2026

(54) METHOD OF MANUFACTURING SEMICONDUCTOR-METAL CONTACTS OF A SOLAR CELL AND SOLAR CELL

(71) Applicant: "INTERNATIONAL SOLAR ENERGY RESEARCH CENTER KONSTANZ", ISC KONSTANZ E.V., Konstanz (DE)

(72) Inventors: Florian BUCHHOLZ, Konstanz (DE); Haifeng CHU, Konstanz (DE); Valentin MIHAILETCHI, kONSTANZ (DE); Jan LOSSEN, Koeln (DE)

(21) Appl. No.: 18/996,491

(22) PCT Filed: Jul. 14, 2023
(86) PCT No.: PCT/EP2023/069706

§ 371 Date: Jan. 17, 2025

(30) Foreign Application Priority Data
Jul. 19, 2022 (DE) 10 2022 118 063.8

(51) Int. Cl. H10F 77/20; H10F 77/30

(52) U.S. Cl. CPC H10F 77/219; H10F 77/311

(57) ABSTRACT

A method for producing the semiconductor-metal contact structure of a solar cell is provided, in which a first paste, ink or suspension containing metal particles is first applied locally to the semiconductor surface at a plurality of points and is fired or sintered in a first firing or sintering process, so that localized semiconductor-metal contact regions are produced which are separated from one another, metal contact regions are produced, and in which local, mutually separated semiconductor-metal contacts thus produced are subsequently bonded together to form the semiconductor-metal contact structure of the solar cell by a second application of a paste, ink or suspension containing metal particles and a second, separate firing or sintering or curing process.

The electrical contacting of the solar cells through the integration of suitable semiconductor-metal contacts plays a decisive role in the production of the most efficient solar cells possible, as recombination currents at the metal-semiconductor interface limit the performance of modern solar cells.

Known ways of producing these contacts depend on the properties of the semiconductor surfaces to be contacted. For n+-doped silicon (likewise for diffusion-doped surfaces and doped polysilicon layers), it is possible to use silver pastes that are applied locally to form the contact and then exposed to elevated temperatures in a firing or sintering step, but these are expensive due to their high silver content. For contacting p+-doped silicon, especially for p+-doped polysilicon layers, good results are not achieved with pure silver pastes.

The silver-aluminum pastes and aluminum pastes that are also available do not lead to satisfactory results due to rapid alloy formation between aluminum and silicon. Since aluminum in these pastes is present in larger particles, typically with a diameter >1 μm, an alloy several hundred nanometers deep is created in the p+ doped silicon or in the polysilicon layer, which is associated with a high level of recombination. For this reason, metallization by means of PVD (Physical Vapor Deposition) coating is also used, particularly for contacting p+ polysilicon, but this involves considerable effort and is therefore also expensive.

These problems also exist in particular when it comes to contacts that use the TOPCon (tunnel oxide passivating contacts) principle, in which the entire surface is passivated with a 1-10 nm thick tunnel oxide layer and the contact is made via a p+ polysilicon layer that is typically 50-200 μm thick. The main problem here is that penetration of the thin tunnel oxide layer must be avoided in order to prevent recombination at metal contacts.

The task of the invention is therefore to provide a method for the cost-effective production of semiconductor-metal contacts with low recombination currents of a solar cell and a solar cell with semiconductor-metal contacts with low recombination currents, whereby the reduced area contributes decisively to the formation of a good metal-semiconductor contact, in contrast to conventional point contact methods, which have the aim of minimizing the contact area. This problem is solved by a method with the features of claim 1 and a solar cell with the features of claim 10.

In the method according to the invention for manufacturing the semiconductor-metal contact structure of a solar cell, a first paste, ink or suspension containing metal particles is first applied locally to the semiconductor surface at a plurality of discrete locations, which are fired or sintered in a first firing or sintering process, in which the structures are briefly (which in the context of this description is to be understood in particular as a period of typically 30 to 180 seconds) exposed to a temperature profile in a continuous furnace, which typically reaches peak temperatures of over 700° C., usually over 750° C. for a few seconds, so that local semiconductor-metal contacts which are spatially and/or electrically separated from one another are produced. If such local, mutually separated semiconductor-metal contacts are arranged on a line, this results, for example, in a dotted or dashed line, which can be produced, for example, by applying such a line with the first paste, ink or suspension containing metal particles to the semiconductor surface, e.g. by screen printing or stencil printing or dispensing or inkjetting, and then firing or sintering or curing.

In other words, the complete contact structure necessary for the operation of the solar cell is not yet created in these steps of the process according to the invention, but is only created in the further course of the process, namely by the fact that local semiconductor-metal contacts thus created are subsequently separated from one another by applying a—preferably but not necessarily second, i.e. differently composed and in particular containing other metal particles or other glass frits—metal particle paste, This is done by applying a paste, ink or suspension containing metal particles, preferably but not necessarily a second paste, i.e. metal particles with a different composition and in particular containing other metal particles or other glass frits, and a second, separate firing or sintering process to join them together to form the semiconductor-metal contact structure of the solar cell.

It is important to emphasize that this is a separate firing or sintering process in which the local, separate semiconductor-metal contacts are already created. Indeed, studies by the inventors have shown that a process in which the first paste, ink or suspension containing metal particles is applied at discrete locations and bonded together with the second paste, ink or suspension containing metal particles before they have been fired or sintered or cured does not result in the formation of metal-semiconductor contacts of the desired quality.

It should be noted—even if this is already clear from the fact that the process is used to produce a semiconductor-metal contact structure of a solar cell—that the term “semiconductor surface” does not refer to the untreated surface of the silicon wafer, but to the surface of the solar cell, which is typically formed by a dielectric layer.

The first paste, ink or suspension containing metal particles can be silver pastes, inks or suspensions with an admixture of glass frit, such as those already used to form semiconductor-metal contacts in the case of n+ silicon or polysilicon. These can also be pure silver pastes, inks or suspensions.

Surprisingly, it turns out that these pastes, inks or suspensions for local, separated semiconductor-metal contacts that do not exceed a certain size can also be used for contacting other semiconductor surfaces with low contact resistance, in particular p+ polysilicon, without high recombination currents occurring.

In particular, the area of the individual local, mutually separated semiconductor-metal contacts, which are created with the first paste containing metal particles during the first firing or sintering, is smaller than 50,000 μm² per contact, preferably smaller than 12500 μm², most preferably smaller than 4,000 μm², in order to largely avoid lateral equalizing currents.

For this reason, it is also preferable if the individual local, separate semiconductor-metal contacts are circular or rectangular and if their largest dimension is less than 100 μm, preferably less than 40 μm.

In another possible design, the individual local, separated semiconductor-metal contacts are line-shaped with a length of less than 500 μm and preferably less than 250 μm and a width of less than 100 μm and preferably less than 50 μm.

It is also worth noting that a second paste, ink or suspension containing metal particles can be made from materials that would otherwise not be considered for the production of metal-semiconductor contacts for solar cells, for example because their initial strength is too low. In addition, after the first firing or sintering step, pastes containing first and second metal particles can be combined, for which this is not normally the case due to their mixing behavior or chemical reactions with each other. For example, the first metal particle-containing paste, ink or suspension may be based on silver particles, and the second metal particle-containing pastes, inks or suspensions used in the process to electrically conductively connect the initially generated individual local, separated semiconductor-metal contacts to each other may, for example, contain aluminum or copper. Such pastes, inks and suspensions can be very good conductors; at the same time, however, they are much less expensive than silver-containing pastes, so that the method according to the invention can lead to cost advantages even in cases in which the metal-semiconductor contact structures of the solar cell can in principle be produced on the basis of a single silver-containing paste, ink or suspension, for example in the contacting of n+ polysilicon layers.

In a preferred embodiment of the method, the second firing, sintering or curing process takes place at a lower temperature than the first firing or sintering process and which is not sufficient to completely penetrate the top layer of the substrate, usually a dielectric layer (“non-firing”).

It is particularly advantageous if the first firing or sintering process is a fast process with a peak temperature of over 700° C., which is present for less than 60 seconds.

Preferably, a silver-containing paste, ink or suspension is used when applying the first paste, ink or suspension containing metal particles in order to obtain the best possible properties of the local contacts.

Particularly good results are also achieved if a paste, ink or suspension containing copper or aluminum is used for the second application of a paste, ink or suspension containing metal particles.

Preferably, but not necessarily, two different pastes, inks or suspensions are therefore used for the first application and the second application.

The solar cell according to the invention with a semiconductor-metal contact structure is characterized in that at least one contact of one polarity is formed by a plurality of local, mutually separated semiconductor-metal contacts formed from a first fired or sintered paste, ink or suspension containing metal particles, which are connected to one another via conductor sections formed from a—preferably second, i.e. differently composed—fired or sintered paste, ink or suspension containing metal particles. This specific structure ensures that low recombination currents occur at the metal contacts, thus achieving a high open-clamp voltage (Voc) and a high energy conversion efficiency.

It should be noted in this context that this structure can be detected on the solar cell by analyzing the structure of the different types of sections of the semiconductor-metal contact structure and their transition areas, for example by the fact that a different contact interface is created in the areas that are contacted in the first and second steps, with a different surface area of open dielectric, or with a different number of silver crystallites in the silicon surface.

Such a solar cell can be a back-contact solar cell in which differently doped areas are arranged next to each other on the back of the solar cell. It is also possible that at least one polarity of the solar cell is passivated by a passivating contact structure.

The solar cell can also be a double-sided solar cell with the contact for one polarity on the front and the contact for the other polarity on the back, in particular the solar cell can be a TOPCon solar cell.

Since the invention allows the same paste, ink or suspension containing metal particles to be used for both n− and p− contact areas, the application sequence is simplified, especially for back-contact solar cells. At least one application step can be saved. If screen printing is used, incompletely dried printing paste is prevented from being detached in the second printing step due to friction of the screen. Furthermore, the printing process for the production of contacts for the second polarity is prevented from being disturbed by structures already printed on the cell.

It is particularly preferred if the first paste, ink or suspension containing metal particles is silver-containing and/or if the second paste, ink or suspension containing metal particles is a copper-containing or aluminum-containing paste, ink or suspension. Silver-containing, copper-containing or aluminum-containing is to be understood in such a way that in particular pure silver, copper or aluminum pastes also fall under this term and can be preferred embodiments.

The invention is explained in more detail below with reference to figures showing an example embodiment. It shows:

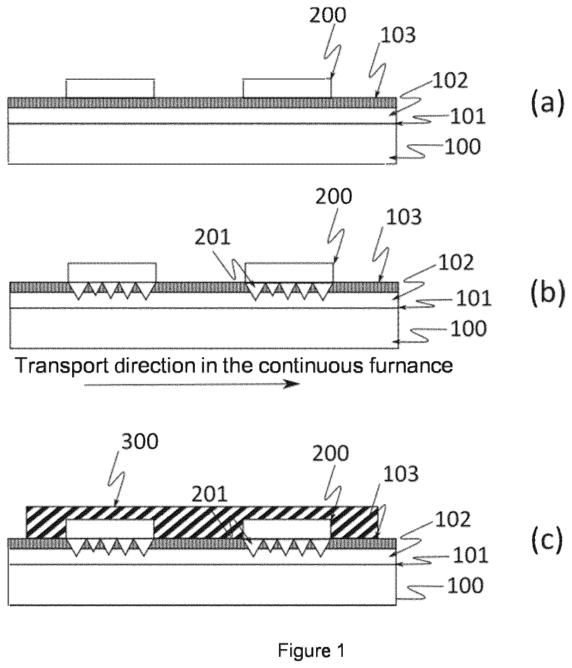

FIG. 1: Three stages in an embodiment of the method according to the invention,

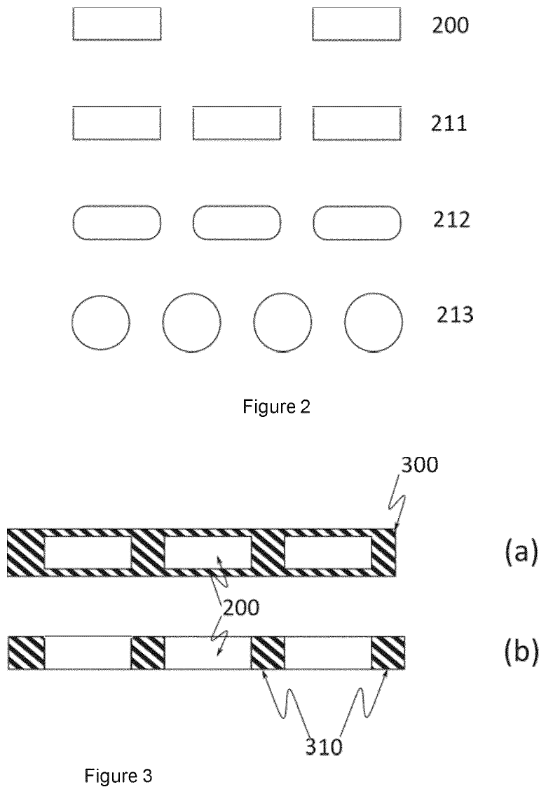

FIG. 2: an exemplary selection of possible shapes for the first metallization layer,

FIG. 3: two possible embodiments for combinations of the two different metallization layers, and

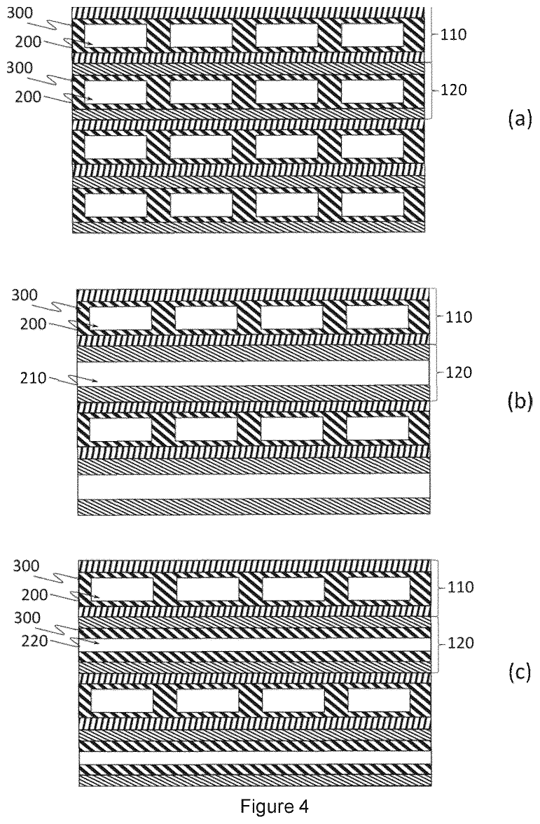

FIG. 4: Various back-contact solar cells according to variants of the invention

FIG. 1 shows three stages in a typical implementation of the process according to the invention, namely after the application of the first contact layer (a), the subsequent firing or sintering (b) and the application of the second contact layer with subsequent firing, sintering or curing process at a lower temperature (c).

In section (a) of FIG. 1, a silicon wafer 100 can be seen, on the surface of which a layer of thin tunnel oxide 101 and a p+ polysilicon layer 102 as well as a dielectric 103 are arranged. On this dielectric layer 103 there are a plurality of spots 200 with an applied first paste, ink or suspension containing metal particles.

In the state after the first firing or sintering, which is shown in section (b) of FIG. 1, semiconductor-metal contact sites 201 are formed in the region of these sites 200, so that the sites 200 become local, mutually separated semiconductor-metal contact regions.

After a second application of a paste, ink or suspension 300 containing metal particles and a second, separate firing or sintering or curing process, the state shown in section (c) of FIG. 1 is achieved in which the semiconductor-metal contact structure of the solar cell is connected to each other, in which optimum contact is achieved below the first metallization layer and at the same time good transverse conductivity is achieved due to the second layer.

Furthermore, FIG. 2 shows that instead of rectangular areas, rectangular areas 211 at a smaller distance, oval areas 212 or circular areas 213 can also be created; a variety of other shapes are possible.

FIG. 3 shows two possible embodiments for the structure created by the second application of a paste, ink or suspension 300, 310 containing metal particles and the resulting contacts between the two different metallization layers. For the second layer, as shown in embodiment (a) of FIG. 3, a continuous second conductive layer may be applied, but, as shown in embodiment (b) of FIG. 3, need not be applied. According to the invention, for the purpose of reducing the consumption of paste, ink or suspension of the second metallization layer containing metal particles, the printed patterns may also consist of separated partial sections 310, so that after the second firing, sintering or curing process in FIG. 1, representation (c), a heterogeneous line is formed which consists alternately of sections formed from the first metal paste 200 and the second metal paste 310.

FIG. 4 shows in the partial representations (a) to (c) the different back-contact solar cells with different embodiments of the inventions, whereby the areas 110 are p+ strips and the areas 120 are n+ strips, these are applied alternately, whereby the contacting of the n+ strip is carried out according to the invention without additional application steps.

### LIST OF REFERENCE SYMBOLS

100 Silicon wafers
101 Thin tunnel oxide
102 P+ polysilicon layer
103 Dielectric
110 p+-doped region
120 n+-doped region
200 discrete spots of a first paste, ink or suspension containing metal particles
201 Semiconductor-metal contact point
211 Rectangular area of a first paste, ink or suspension containing metal particles
212 Oval areas of a first paste, ink or suspension containing metal particles
213 Circular spots of a first paste, ink or suspension containing metal particles
210,220 Linear conductive path of a first paste, ink or suspension containing metal particles
300 Second paste, ink or suspension containing metal particles, which is formed into a line shape during the firing, sintering or curing process at a lower temperature.
310 Second paste, ink or suspension containing metal particles, which is applied at a lower temperature during the firing, sintering or curing process, which is complementary

1. Method for producing the semiconductor-metal contact structure of a solar cell, in which a first paste, ink or suspension containing metal particles is first applied locally to the semiconductor surface at a plurality of points and fired or sintered in a first firing or sintering process, so that local, mutually separate semiconductor-metal contact regions are produced, and in which local, mutually separated semiconductor-metal contacts thus produced are subsequently bonded together to form the semiconductor-metal contact structure of the solar cell by a second application of a paste, ink or suspension containing metal particles and a second, separate firing or sintering or curing process.

2. The method according to claim 1, characterized in that the second firing or sintering or curing process takes place at a lower temperature than the first firing or sintering process.

3. The method according to claim 1, characterized in that the first firing or sintering process is a fast process with a peak temperature above 700° C. for less than 60 seconds.

4. Method according to claim 1, characterized in that the area of the individual local semiconductor-metal contacts separated from each other is smaller than 50,000 μm², preferably smaller than 12,500 μm², most preferably smaller than 4,000 μm².

5. Method according to claim 4, characterized in that the individual local, mutually separated semiconductor-metal contacts are circular, oval, or rectangular, rectangular with rounded corners and that their largest dimension is less than 100 μm, preferably less than 40 μm.

6. Method according to claim 4, characterized in that the individual local semiconductor-metal contacts separated from each other are line-shaped with a length which is less than 500 μm and preferably less than 250 μm and with a width which is less than 100 μm and preferably less than 50 μm.

7. Method according to claim 5, characterized in that the individual local semiconductor-metal contacts separated from each other are connected to each other in the second step to form a pattern of parallel lines.

8. The method according to claim 1, characterized in that the first paste, ink or suspension containing metal particles is silver-containing.

9. The method according to claim 1, characterized in that a copper-containing or aluminum-containing paste, ink or suspension is used in the 410 second application of a paste, ink or suspension containing metal particles.

10. The solar cell according to claim 10, characterized in that the solar cell is a back-contact solar cell.

11. Solar cell according to claim 10, characterized in that at least one polarity of the

12. Solar cell according to claim 10, is passivated by a passivating contact structure.

13. The solar cell according claim 10, characterized in that the semiconductor-metal contacts of both polarities are made of the same first metal particle-containing paste, ink or suspension.

14. Solar cell according to claim 13, characterized in that the semiconductor-metal contacts of both polarities are printed together.

15. Solar cell according to claim 9, characterized in that the solar cell is a TOPCon solar cell.

16. The solar cell according to claim 10, characterized in that the first paste, ink or suspension containing metal particles is silver-containing.

17. The method according to claim 10, characterized in that the second metal particle-containing paste, ink or suspension is a copper-containing or aluminum-containing paste, ink or suspension.
